(19) United States
(12) Patent Application Publication
(10) Pub. No.: US 2020/0343876 A1
(43) Pub. Date: Oct. 29, 2020

(54) BAND-PASS FILTERING CIRCUIT AND MULTIPLEXER

(71) Applicant: ANHUI ANUKI TECHNOLOGIES CO., LTD., Hefei, Anhui (CN)

(72) Inventors: Qilin SHI, Hefei, Anhui (CN); Chengjie ZUO, Hefei, Anhui (CN); Jun HE, Hefei, Anhui (CN)

(21) Appl. No.: 16/765,392

(22) PCT Filed: Oct. 9, 2018
(86) PCT No.: PCT/CN2018/109385

§ 371 Date: May 19, 2020

(30) Foreign Application Priority Data
Jun. 4, 2018 (CN) 201810563591.1
Jun. 4, 2018 (CN) 201820854823.4

(51) Int. Cl. H03H 9/54; H03H 9/70

(52) U.S. Cl. CPC H03H 9/542; H03H 9/70

(57) ABSTRACT

Provided is a band-pass filter circuit and multiplexer. The band-pass filter circuit includes a first filter circuit unit. The first filter circuit unit comprises: a first acoustic resonator and a second acoustic resonator connected in series; a first circuit element connected in parallel with the first acoustic resonator; a second circuit element connected in parallel with the second acoustic resonator; and a third circuit element having a first end connected with a common connection point of the first acoustic resonator and the second acoustic resonator, and a second end grounded. The first circuit element and the second circuit element are capacitive, the third circuit element is inductive; or the first circuit element and the second circuit element are inductive, the third circuit element is capacitive.

This application claims priority to Chinese patent applications No. 201810563591.1, 201820854823.4 filed with China patent office on Jun. 4, 2018, contents of both of which are incorporated herein by reference in their entireties.

### TECHNICAL FIELD

Embodiments of the present application relate to filter technique and, for example, to a band-pass filter circuit and multiplexer.

### BACKGROUND

Filter circuits are widely used in integrated circuits, and for example used in multiplexers in integrated circuits. The design of a multiplexer with a wide frequency band and a high suppression is always a bottleneck for the design of integrated circuits.

Filtering through an acoustic wave filter may solve a problem that a high suppression cannot be achieved by a filter circuit. However, the acoustic wave filter, which has an advantage of high suppression, cannot achieve a wide frequency band.

How to maintain a high suppression and a wide bandwidth is always a problem in the design of multiplexers.

### SUMMARY

The present application provides a band-pass filter circuit and multiplexer, to realize a design of filter circuit and multiplexer with characteristics of a wide bandwidth and a high suppression.

In a first aspect, the present application provides a band-pass filter circuit. The band-pass filter circuit includes a first filter circuit unit.

The first filter circuit unit includes:

a first acoustic resonator and a second acoustic resonator connected in series;

a first circuit element, which is connected in parallel with the first acoustic resonator;

a second circuit element, which is connected in parallel with the second acoustic resonator; and

a third circuit element, which has a first end connected with a common connection point of the first acoustic resonator and the second acoustic resonator, and a second end grounded.

The first circuit element and the second circuit element are capacitive, the third circuit element is inductive; or the first circuit element and the second circuit element are inductive, the third circuit element is capacitive;

In an embodiment, the band-pass filter circuit further includes a second filter circuit unit connected in series with the first filter circuit unit, the first filter circuit unit and the second filter circuit unit each include a first end and a second end;

the first acoustic resonator and the second acoustic resonator are connected in series between the first end of the first filter circuit unit and the second end of the first filter circuit unit;

the second end of the second filter circuit unit is connected with the first end of the first filter circuit unit, or the first end of the second filter circuit unit is connected with the second end of the first filter circuit unit.

In an embodiment, the second filter circuit unit is a low-pass filter circuit unit, the first circuit element and the second circuit element are capacitive, the third circuit element is inductive.

In an embodiment, the second filter circuit unit is a high-pass filter circuit unit, the first circuit element and the second circuit element are inductive, and the third circuit element is capacitive.

In an embodiment, the second filter circuit unit is an active filter unit or a passive filter unit.

In a second aspect, the present application provides a multiplexer. The multiplexer includes at least one band-pass filter circuit according to the first aspect.

In an embodiment, the multiplexer further includes a first end and at least two second ends;

the first filter circuit unit and the second filter circuit unit of each of the at least one band-pass filter circuit are connected in series between the first end of the multiplexer and one of the second ends of the multiplexer.

In an embodiment, the multiplexer further includes at least one third filter circuit unit;

the at least one third filter unit is connected between the first end of the multiplexer and one of the second ends of the multiplexer, and the at least one third filter unit is connected in parallel with the at least one band-pass filter circuit.

In an embodiment, the first end of the multiplexer and the second ends of the multiplexer each serve as an input and output end.

The band-pass filter circuit and multiplexer according to the present application use a combination of a lumped element and an acoustic wave resonator in the circuit to form a filter circuit, and the filter circuit has characteristics of a high suppression and a wide frequency band.

### BRIEF DESCRIPTION OF DRAWINGS

FIG. 1 is a circuit diagram of a band-pass filter circuit according to an embodiment.

FIG. 2 is a circuit diagram of another band-pass filter circuit according to an embodiment.

FIG. 3 is a circuit diagram illustrating connection ends of a band-pass filter circuit according to an embodiment.

FIG. 4 is a circuit diagram illustrating connection ends of another band-pass filter circuit according to an embodiment.

FIG. 5 is an S-parameter simulation diagram for the circuit shown in FIG. 3 according to an embodiment.

FIG. 6 is an S-parameter simulation diagram for the circuit shown in FIG. 3 according to an embodiment.

FIG. 7 is a circuit diagram of a multiplexer according to an embodiment.

### DETAILED DESCRIPTION

The present application will be further described in detail with reference to the accompanying drawings and embodiments. It is to be understood that the embodiments set forth below are intended to illustrate and not to limit the present application. Additionally, it is to be noted that to facilitate description, only part, not all, of structures related to the present application are illustrated in the accompanying drawings.

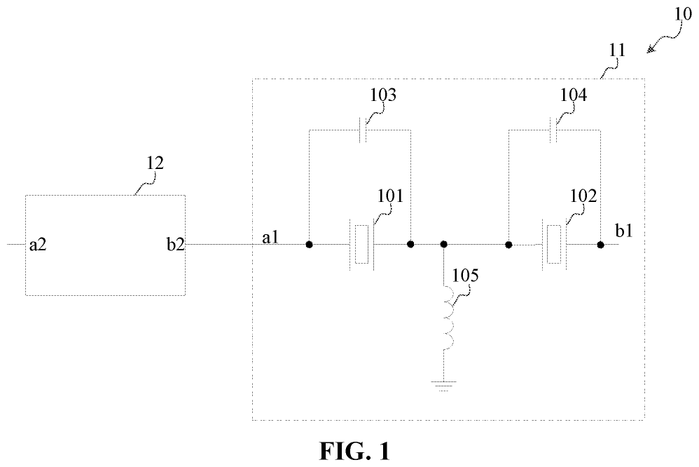

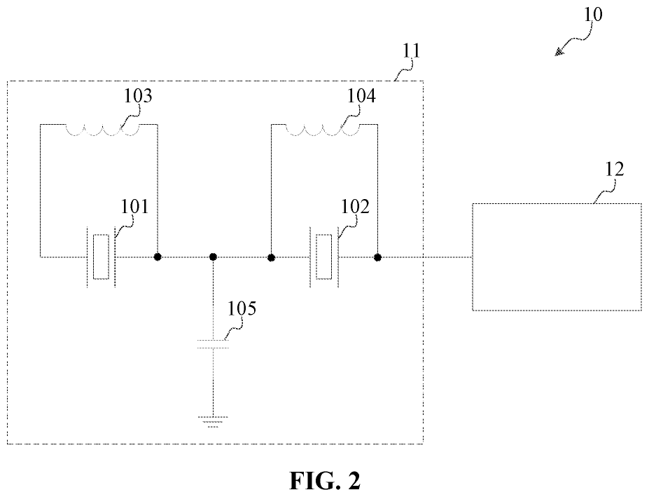

FIG. 1 is a circuit diagram of a band-pass filter circuit according to an embodiment. FIG. 2 is a circuit diagram of another band-pass filter circuit according to an embodiment.

Referring to FIGS. 1 and 2, the band-pass filter circuit includes a first filter circuit unit 11.

The first filter circuit unit 11 includes:

a first acoustic resonator 101 and a second acoustic resonator 102, which are connected in series;

a first circuit element 103, which is connected in parallel with the first acoustic resonator 101;

a second circuit element 104, which is connected in parallel with the second acoustic resonator 102; and

a third circuit element 105, which has a first end connected with a common connection point of the first acoustic resonator 101 and the second acoustic resonator 102, and a second end grounded.

In the circuit shown in FIG. 1, the first circuit element 103 and the second circuit element 104 are capacitive, the third circuit element 105 is inductive.

In the circuit shown in FIG. 2, the first circuit element 103 and the second circuit element 104 are inductive, the third circuit element 105 is capacitive. The first acoustic resonator 101 and the second acoustic resonator 102 may be implemented by surface acoustic wave (SAW), bulk acoustic wave (BAW), film bulk acoustic resonator (FBAR), but not limited thereto. The first circuit element 103, the second circuit element 104 and the third circuit element 105 may be implemented by low temperature co-fired ceramic (LTCC) and surface mount devices (SMD), but not limited thereto.

A conventional filter circuit unit usually includes several lumped elements such as capacitor, inductor and resistor. The composed filter circuit has a relatively wide frequency band and a poor suppression characteristic. Alternatively, the filter circuit unit uses several acoustic resonators, the suppression characteristic of the filter circuit unit is improved, but the filter circuit unit has a relatively narrow frequency band. During the research, the inventor found that the first filter circuit unit 11 consisting of the first circuit element 103, the second circuit element 104, the third circuit element 105 and two acoustic resonators (the first acoustic resonator 101 and the second acoustic resonator 102) has not only a high suppression, but also a wide frequency band. The circuit characteristics are greatly improved. The band-pass filter circuit unit according to the embodiments of the present application is composed of a combination of a low-pass or high-pass filter circuit unit, an acoustic resonator, a capacitive element and a resistive element, and has characteristics of a high suppression and a wide frequency band.

Also referring to FIGS. 1 and 2, the band-pass filter circuit according to the embodiments of the present application may further include a second filter circuit unit 12 connected in series with the first filter circuit unit 11. The first filter circuit unit 11 and the second filter circuit unit 12 each comprise a first end and a second end. Referring to FIG. 1, the first filter circuit 11 has connection ends a1 and b1, which respectively serve as the first end of the first filter circuit unit 11 and the second end of the first filter circuit unit 11. Those skilled in the art may understand that, the connection ends a1 and b1 may also respectively serve as the second end of the first filter circuit unit 11 and the first end of the first filter circuit unit 11. Similarly, connection ends a2 and b2 may respectively serve as the first end of the second filter circuit unit 12 and the second end of the second filter circuit unit 12, or serve as the second end of the second filter circuit unit 12 and the first end of the second filter circuit unit 12. Moreover, two unconnected connection ends, which are located between the first filter circuit unit 11 and the first filter circuit unit 12, may serve as the first end of the band-pass filter circuit and the second end of the band-pass filter circuit. For example, in FIG. 1, the connection ends b1 and a2 respectively serve as the first end of the band-pass filter circuit 10 and the second end of the band-pass filter circuit 10, or serve as the second end of the band-pass filter circuit 10 and the first end of the band-pass filter circuit 10. The first end of the band-pass filter circuit 10 may serve as an input end or an output end, and the second end may also serve as an input end or an output end.

In an embodiment, the first acoustic resonator 101 and the second acoustic resonator 102 are connected in series between the first end of the first filter circuit unit 11 and the second end of the first filter circuit unit 11;

the second end of the second filter circuit unit 12 is connected with the first end of the first filter circuit unit, or the first end of the second filter circuit unit 12 is connected with the second end of the first filter circuit unit 11.

It should be noted that the second filter circuit unit 12 may be a filter circuit unit in the related art, i.e. a circuit capable of implementing filtering. The second filter circuit unit 12 is an active filter unit or a passive filter unit, which may be configured according to an actual application circuit, which is not limited by the embodiments of the present application.

In the embodiments of the present application, with further reference to FIG. 1, the second filter circuit unit 12 may be a low-pass filter circuit unit; accordingly, the first circuit element 103 and the second circuit element 104 are capacitive, and the third circuit element 105 is inductive. That is, the first circuit element 103, the second circuit element 104 and the third circuit element 105 compose a high-pass filter circuit unit. The first filter circuit unit 11 and the second filter circuit unit 12 compose a band-pass filter circuit.

In the embodiments of the present application, with further reference to FIG. 2, the second filter circuit unit 12 may be a high-pass filter circuit unit, accordingly, the first circuit element 103 and the second circuit element 104 are inductive, and the third circuit element 105 is capacitive. That is, the first circuit element 103, the second circuit element 104 and the third circuit element 105 compose a low-pass filter circuit unit. The first filter circuit unit 11 and the second filter circuit unit 12 compose a band-pass filter circuit.

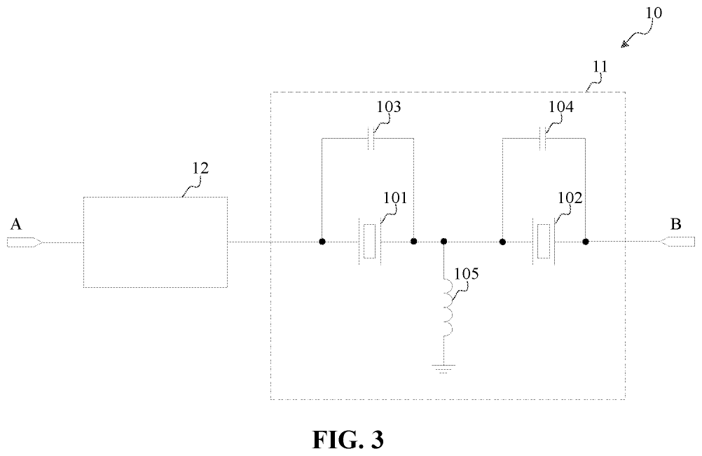

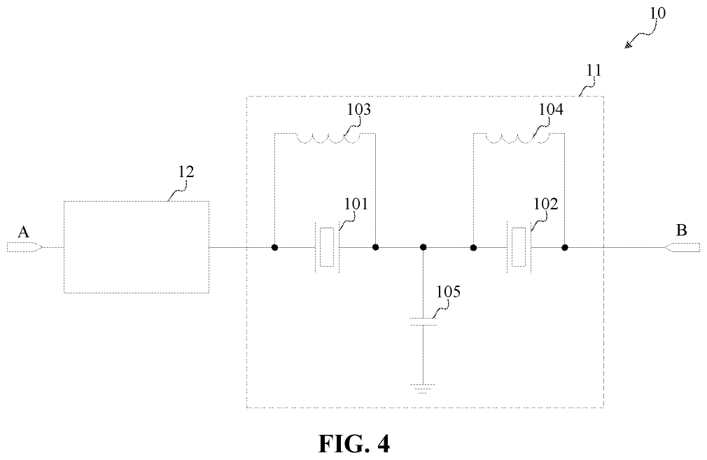

FIG. 3 is a circuit diagram illustrating connection ends of a band-pass filter circuit according to an embodiment. FIG. 4 is another circuit diagram illustrating connection ends of a band-pass filter circuit according to an embodiment. Referring to FIGS. 3 and 4, based on above-mentioned embodiments, the first filter circuit unit 11 and the second filter circuit unit 12 are connected in series between the first end A of the band-pass filter circuit 10 and the second end B of the band-pass filter circuit 10. The first end A is an input end and the second end B is an output end, and/or the second end B is an input end and the first end A is an output end. The ends may be configured according to specific use requirements.

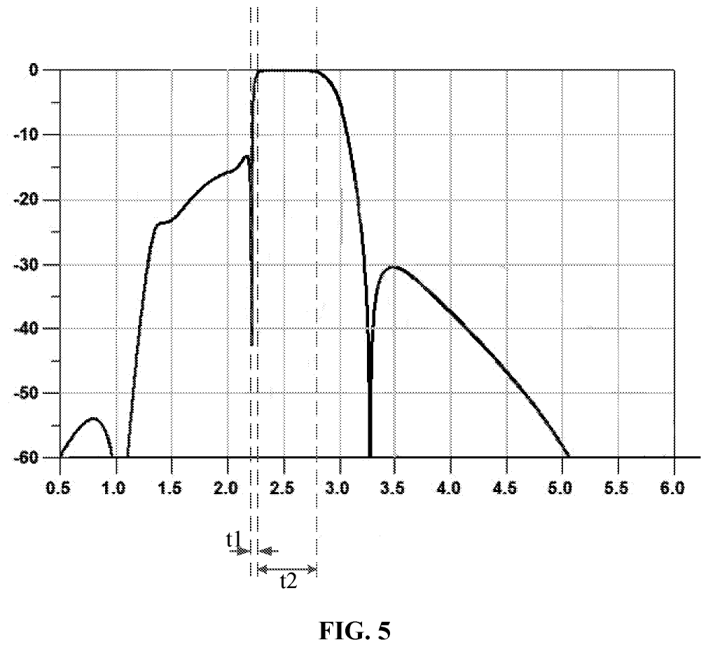

FIG. 5 is a S-parameter simulation diagram for the circuit shown in FIG. 3 according to an embodiment. Referring to FIG. 5, the abscissa has a unit of GHz and the ordinate has a unit of dB. The t1 represents bandwidth of a transition band of the band-pass filter circuit. This bandwidth is small, which shows that the circuit in FIG. 3 has a high suppression characteristic. The t2 represents a pass band frequency of the band-pass filter circuit with a relatively wide frequency band of about 500 MHz (2.3 GHz-2.8 GHz). Reference is made to the table below. The table shows comparison between parameters of the filter circuit (filter) according to the embodiments of the present application, a LTCC filter and a SAW filter in the f related art.

| | | Bandwidth of | |
|---|---|---|---|
| | Pass Band | Transition | |
| | Frequency (t2) | Band (t1) | |
| LTCC Filter | 2300-2800 MHz (500 MHz) | 230 | MHz |
| SAW Filter | 2300-2400 MHz (100 MHz) | 60 | MHz |

| | | |
|---|---|---|
| Filter according to the | 2300-2800 MHz (500 MHz) | 1 MHz-200 MHz |
| embodiments of the | | |
| present application | | |

It can be seen that, although the LTCC filter has a wider pass band, the LTCC filter has the t1 equaling to 230 MHz, thus having a wider transition band and a poorer out-band suppression; the SAW filter has a narrower transition band and thus a high suppression characteristic, but a narrower pass band. The filter according to the embodiments of the present application not only has a wide pass band, but also a high suppression characteristic. The bandwidth of the transition band may be designed by using different filter processes. The performance of multiplexer is greatly improved compared with filters in the related art.

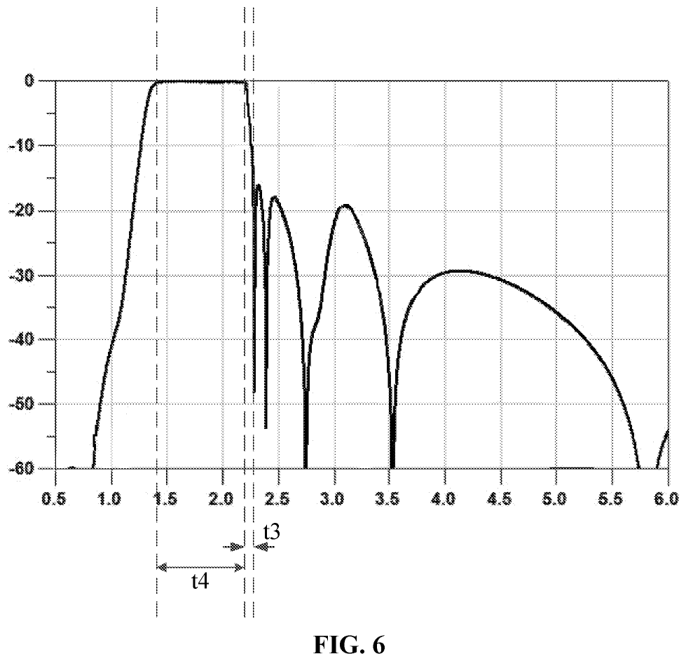

FIG. 6 is a S-parameter simulation diagram for the circuit shown in FIG. 3 according to an embodiment. Referring to FIG. 6, the abscissa has a unit of GHz and the ordinate has a unit of dB. The t3 represents the bandwidth of a transition band of the band-pass filter circuit. The bandwidth is small, which shows that the circuit in FIG. 4 has a high suppression characteristic. The t4 represents a pass band frequency of the band-pass filter circuit with a relatively wide frequency band of about 800 MHz (1.4 GHz-2.2 GHz).

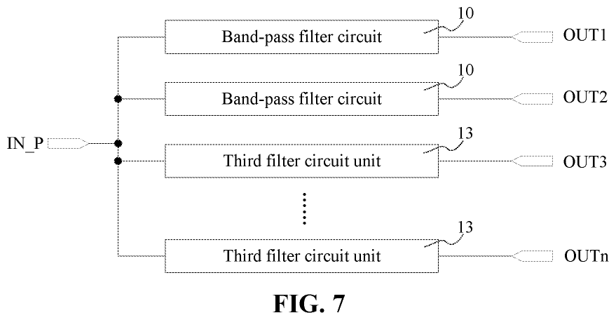

Based on a same inventive concept, an embodiment also provides a multiplexer. Referring to FIG. 7, the multiplexer includes at least one band-pass filter circuit 10 according to any embodiment of the present application. The multiplexer further includes a first end and at least two second ends, such as one first end IN_P and a set of N second ends, which includes OUT1, OUT2, . . . , OUTn respectively.

The first filter circuit unit and the second filter circuit unit of each of the at least one band-pass filter circuit 10 are connected in series between the first end of the multiplexer and one of the second ends of the multiplexer. For example, the first filter circuit unit and the second filter circuit unit of a first band-pass filter circuit 10 are connected in series between the first end IN_P of the multiplexer and the second end OUT1 of the multiplexer. A band-pass filter circuit according to any embodiment of the present application is used between the first end of the multiplexer and at least one of the second ends of the multiplexer. The multiplexer has characteristics of a high suppression and a wide frequency band. The first end of the multiplexer and the second ends of the multiplexer each serve as an input and output end. That is, the multiplexer is usually bidirectional, i.e., each of the first end and the second ends may not only input signals, but also output signals.

In an embodiment, with further reference to FIG. 7, the multiplexer according to the embodiments of the present application further includes at least one third filter circuit unit 13. The at least one third filter unit 13 is connected between the first end of the multiplexer and one of the second ends of the multiplexer, and the at least one third filter unit is connected in parallel with the at least one band-pass filter circuit 10. That is, in the multiplexer according to the embodiments of the present application, in addition to the band-pass filter circuit according to the present application, other kinds of filter circuit unit may also be included. The third filter circuit unit 13 may be a low-pass filter circuit unit, a high-pass filter circuit unit or a band-pass filter circuit unit, which may be selected according to a specific application circuit.

1. A band-pass filter circuit, comprising a first filter circuit unit;
wherein the first filter circuit unit comprises:
a first acoustic resonator and a second acoustic resonator connected in series;
a first circuit element, which is connected in parallel with the first acoustic resonator;
a second circuit element, which is connected in parallel with the second acoustic resonator; and
a third circuit element, which has a first end connected with a common connection point of the first acoustic resonator and the second acoustic resonator, and a second end grounded;
wherein the first circuit element and the second circuit element are capacitive, the third circuit element is inductive; or the first circuit element and the second circuit element are inductive, the third circuit element is capacitive.

2. The band-pass filter circuit according to claim 1, further comprising a second filter circuit unit connected in series with the first filter circuit unit, the first filter circuit unit and the second filter circuit unit each comprise a first end and a second end;
wherein the first acoustic resonator and the second acoustic resonator are connected in series between the first end of the first filter circuit unit and the second end of the first filter circuit unit;
wherein the second end of the second filter circuit unit is connected with the first end of the first filter circuit unit, or the first end of the second filter circuit unit is connected with the second end of the first filter circuit unit.

3. The band-pass filter circuit according to claim 2, wherein the second filter circuit unit is a low-pass filter circuit unit, the first circuit element and the second circuit element are capacitive, the third circuit element is inductive.

4. The band-pass filter circuit according to claim 2, wherein the second filter circuit unit is a high-pass filter circuit unit, the first circuit element and the second circuit element are inductive, and the third circuit element is capacitive.

5. The band-pass filter circuit according to claim 2, wherein the second filter circuit unit is an active filter unit or a passive filter unit.

6. A multiplexer, comprising at least one band-pass filter circuit,
wherein the band-pass filter circuit comprises a first filter circuit unit;
wherein the first filter circuit unit comprises:
a first acoustic resonator and a second acoustic resonator connected in series;
a first circuit element, which is connected in parallel with the first acoustic resonator;
a second circuit element, which is connected in parallel with the second acoustic resonator; and
a third circuit element, which has a first end connected with a common connection point of the first acoustic resonator and the second acoustic resonator, and a second end grounded;
wherein the first circuit element and the second circuit element are capacitive, the third circuit element is inductive; or the first circuit element and the second circuit element are inductive, the third circuit element is capacitive.

7. The multiplexer according to claim 6, further comprising a first end and at least two second ends;
wherein the first filter circuit unit and the second filter circuit unit of each of the at least one band-pass filter circuit are connected in series between the first end of the multiplexer and one of the second ends of the multiplexer.

8. The multiplexer according to claim 7, further comprising at least one third filter circuit unit;
wherein the at least one third filter unit is connected between the first end of the multiplexer and one of the second ends of the multiplexer, and the at least one third filter unit is connected in parallel with the at least one band-pass filter circuit.

9. The multiplexer according to claim 7, wherein the first end of the multiplexer and the second ends of the multiplexer each serve as an input and output end.

10. The multiplexer according to claim 8, wherein the first end of the multiplexer and the second ends of the multiplexer each serve as an input and output end.

11. The multiplexer according to claim 6, further comprising a second filter circuit unit connected in series with the first filter circuit unit, the first filter circuit unit and the second filter circuit unit each comprise a first end and a second end;
wherein the first acoustic resonator and the second acoustic resonator are connected in series between the first end of the first filter circuit unit and the second end of the first filter circuit unit;
wherein the second end of the second filter circuit unit is connected with the first end of the first filter circuit unit, or the first end of the second filter circuit unit is connected with the second end of the first filter circuit unit.

12. The multiplexer according to claim 11, wherein the second filter circuit unit is a low-pass filter circuit unit, the first circuit element and the second circuit element are capacitive, the third circuit element is inductive.

13. The multiplexer according to claim 11, wherein the second filter circuit unit is a high-pass filter circuit unit, the first circuit element and the second circuit element are inductive, and the third circuit element is capacitive.

14. The multiplexer according to claim 11, wherein the second filter circuit unit is an active filter unit or a passive filter unit.
